(19) United States
(12) Patent Application Publication
(10) Pub. No.: US 2006/0120201 A1
(43) Pub. Date: Jun. 8, 2006

(54) Semiconductor memory device

(75) Inventors: Masakazu Kurata, Osaka-shi (JP); Mitsuaki Hayashi, Kyoto-shi (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/267,195

(22) Filed: Nov. 7, 2005

(30) Foreign Application Priority Data
Nov. 16, 2004 (JP) 2004-331687

(51) Int. Cl. G11C 8/00

(52) U.S. Cl. 365/230.03

(57) ABSTRACT

According to a conventional semiconductor memory device, in a replica circuit composed of a plurality of dummy bit lines, an off leakage current of a transistor has been significantly increased with the advance of a semiconductor microfabrication technology, so that the dummy bit line has not been able to be charged to a desired potential due to the off leakage current when charging. As a result of this, since a charging period or a discharging period of the dummy bit line is also different from a desired period, the optimal operation timing may not be set.

In a dummy memory cell array, in order to connect a drain region 21 and a first dummy bit line 25, the first dummy bit line 25 is connected via contact and via holes 28 through 30 and metal electrodes 23 and 24, while a second dummy bit line 46 does not contact to a drain region 47.

### BACKGROUND OF THE INVENTION

1. Field of the Invention

The present invention relates to a semiconductor memory device, such as a MASK ROM or the like.

2. Description of the Prior Art

In a semiconductor memory device, such as a conventional MASK ROM, as one of the techniques for reducing current consumption, in order to appropriately control a readout operation time, a replica circuit including a dummy sense amplifier circuit and a dummy memory cell circuit having the same configuration as that of a normal sense amplifier circuit and memory cell circuit has been utilized. Hereinafter, referring to the drawings, an operation method of the replica circuit in the conventional MASK ROM will be explained.

FIG. 7 is a diagram of a readout circuit of the conventional MASK ROM. A sense amplifier circuit 1 includes a P-type transistor 2 receiving a precharge signal NPR as a gate input, an N-type transistor 3 connected to the P-type transistor 2 in series, an inverter 4 receiving a source node SA of the N-type transistor 3, and supplying an output to a gate input of the N-type transistor 3, an inverter chain 5 receiving the SA and outputting an SOUTO, and a charge circuit 6 receiving the NPR and outputting the SA. The charge circuit 6 is composed of a P-type transistor 6 (1) and an N-type transistor 6 (2). A column gate 7 is composed of n (n in number) N-type transistors 8 (1) through 8(n), which receive column selection signals CL1 through CLn as gate inputs, respectively, and are connected between the SA and bit lines BL1 through BLn. A memory cell array 9 is composed of memory cells 10 (1, 1) through 10 (n, m) (m in number) arranged in an array form, which receive word lines WL1 through WLm as gate inputs, and whose sources are connected to a ground potential. As for these memory cells, according to data to be stored, whether or not the drains thereof are connected to the bit lines is determined during the manufacturing process. Here, it is assumed that the drains of all memory cells are connected to the bit lines. A column selection circuit 16 receives a Y address signal ADY, and outputs the column selection signals CL1 through CLn. A row selection circuit 17 receives an X address signal ADX, and outputs the word lines WL1 through WLm.

In a control signal generating circuit 60, a dummy sense amplifier circuit 11 has a configuration similar to that of the sense amplifier circuit 1. A dummy column gate 12 is composed of transistors 13(1) and 13(2) having the same configuration as that of the column gate 7, wherein the gate inputs of the transistors are connected to a power supply. A dummy memory cell array 14 is composed of dummy memory cells 15 (1, 1) through 15 (2, m) having the same configuration as that of the memory cells 10, for example, one bit line has one bit or more dummy memory cells, wherein the gates of the dummy memory cells are connected to a ground potential and the dummy memory cells are connected to dummy bit lines DBL1 and DBL2. A NAND gate 18 receives an external clock signal CLK and an output of an inverter 20, and outputs the NPR. The inverter 20 receives the output SOUTD of the dummy sense amplifier 11. An inverter 19 receives the clock signal CLK, and outputs an NDPR as an input to the dummy sense amplifier circuit 11.

FIG. 8A is a plan view of a conventional memory cell array, and FIG. 8B, FIG. 8C, and FIG. 8D are a cross-sectional view taken along line A-A of FIG. 8A, a cross-sectional view taken along line B-B of FIG. 8A, and a cross-sectional view taken along line C-C of FIG. 8A, respectively. This memory cell array includes N-type impurity diffusion regions 31 and 21, which are a source region and a drain region formed on a P-type substrate 32, respectively, a channel region disposed between the source region and the drain region, a gate insulating film 33 formed on the channel region, a gate electrode 27 formed on the gate insulating film 33, an isolation region 22 for isolating between memory cell pairs, contact and via holes 28, 29, and 30 provided in interlayer insulation films for interconnecting between the drain region 21 and an upper interconnection, metal electrodes 23 and 24, a bit line 25 composed of a metal interconnection, a metal interconnection 26, which is arranged in parallel with the gate electrode 27 and has the same potential as that of the gate electrode 27, a source potential supply interconnection 39 arranged in parallel with the bit line 25, a P-type impurity diffusion region 40 for supplying a substrate potential, contact and via holes 34, 35, and 36 for interconnecting between the source potential supply interconnection 39 and the P-type impurity diffusion region 40 for supplying the substrate potential, metal electrodes 37 and 38, and contact and via holes 41, 42, and 43 for supplying the source potential.

Hereinafter, referring to a timing chart of FIG. 9, the circuit operation of FIG. 7 will be explained. When the CLK signal is changed from L level to H level at to, the precharge signal NPR via the NAND gate 18 becomes L level. As a result, the P-type transistor 2 turns on and the SA is charged. However, since the drain of the memory cell that is selected by the column signals CL1 through CLn selected by the column selection circuit 16 and by the word lines WL1 through WLm selected by the row selection circuit 17 is connected to the bit line, the level of the SA is not charged to a determination level of the inverter chain 5, so that L level is outputted to the SOUTO. At that time, a penetration current continues to flow via the memory cell 10 while the precharge signal NPR stays in L level. Similarly, when the CLK signal is changed from L level to H level at t0, the precharge signal NDPR via the inverter 19 is becomes L level, and a DSA is charged. Since all dummy memory cells 15 (1, 1) through 15 (2, m) are connected to the dummy bit lines DBL1 and DBL2, and all dummy word lines are fixed to the ground potential, the level of the DSA is charged to the determination level of the inverter chain, and H level is outputted to the SOUTD. Since the SOUTD is inputted to the NAND gate 18 via the inverter 20, the precharge signal NPR is changed to H level to thereby turn off the P-type transistor 2, leading the penetration current to be stopped.

As described above, during the operation period of the sense amplifier, since the replica circuit using the dummy sense amplifier circuit and the dummy memory cell circuit having the same configuration as the normal sense amplifier circuit and the memory cell circuit is configured, the proper timing can be obtained. Moreover, in order to prevent a malfunction due to a completion of the readout operation of the replica circuit prior to a completion of the normal sense amplifier operation owing to a variation in operation caused by the manufacturing variation or the like, a large number of dummy bit lines are provided to thereby secure the timing margin (for example, refer to Japanese Unexamined Patent Publication (Kokai) No. 08-036895).

In recent years, since an off leakage current of a transistor has been significantly increased with the advance of a microfabrication technology, and in the conventional replica circuit in particular, a plurality of dummy bit lines to which all dummy memory cells are connected are utilized, a current supplied from the charge circuit to the dummy bit line has been too short to charge the dummy bit line to the predetermined potential, so that there has been a problem that the desired timing margin has not been able to be secured.

### SUMMARY OF THE INVENTION

In order to solve the aforementioned problem, there is provided a semiconductor memory device of the present invention, including

a first memory cell array arranging a plurality of memory cells equivalent to memory capacity in a matrix form in a bit line direction and a word line direction,

a first column selection circuit and row selection circuit for respectively selecting a bit line and a word line of the first memory cell array corresponding to an address input,

a plurality of first bit line charge circuits which are connected to the first column selection circuit and respectively charge a plurality of the bit lines selected by the first column selection circuit,

a second memory cell array arranging a plurality of memory cells in a matrix form in a bit line direction and a word line direction,

a second column selection circuit for simultaneously selecting a plurality of bit lines of the second memory cell array, and

a single second bit line charge circuit which is connected to the second column selection circuit and charges the plurality of bit lines of the second memory cell array,

wherein in the second memory cell array, among the plurality of bit lines simultaneously selected by the second column selection circuit, all memory cells are connected to at least one row of the bit line, and at lease one row of the bit line does not connect one bit or more memory cells.

According to the aforementioned configuration, a current from a charge circuit to a plurality of dummy bit lines is supplied so sufficiently that a dummy bit can be charged to a predetermined potential, thereby making it possible to secure a desired timing margin.

In the aforementioned configuration, as means for not connecting the memory cell of the second memory array to the bit line, there is provided a configuration in which a drain of the memory cell is not connected to the bit line.

In the configuration described above, as means for not connecting the memory cell of the second memory array to the bit line, there is provided a configuration in which by using the same mask as that for writing data to a MASK ROM, a drain of the memory cell and the bit line are not connected.

In the configuration described above, as means for not connecting the memory cell of the second memory array to the bit line, there is provided a configuration in which a source of the memory cell is not connected to a ground potential.

In the aforementioned configuration, as means for not connecting the memory cell of the second memory cell array to the bit line, there is provided a configuration in which a gate of the memory cell is not arranged.

According to another means for solving the problem, there is provided a semiconductor memory device of the present invention, including

a first memory cell array arranging a plurality of memory cells equivalent to memory capacity in a matrix form in a bit line direction and a word line direction,

a first column selection circuit and row selection circuit for respectively selecting a bit line and a word line of the first memory cell array corresponding to an address input,

a plurality of first bit line charge circuits which are connected to the first column selection circuit and respectively charge a plurality of the bit lines selected by the first column selection circuit,

a second memory cell array arranging a plurality of memory cells in a matrix form in a bit line direction and a word line direction,

a second column selection circuit for simultaneously selecting a plurality of bit lines of the second memory cell array, and

a single second bit line charge circuit which is connected to the second column selection circuit and charges the plurality of bit lines of the second memory cell array,

wherein in the second memory cell array, the plurality of bit lines simultaneously selected by the second column selection circuit do not connect at least one bit or more memory cells.

In the aforementioned configuration, as means for not connecting the memory cell of the second memory cell array to the bit line, there is provided a configuration in which a drain of the memory cell is not connected to the bit line.

In the aforementioned configuration, as means for not connecting the memory cell of the second memory cell array to the bit line, there is provided a configuration in which by using the same mask as that for writing data to a MASK ROM, a drain of the memory cell and the bit line are not connected.

In the aforementioned configuration, as means for not connecting the memory cell of the second memory cell array to the bit line, there is provided a configuration in which a source of the memory cell is not connected to a ground potential.

In the aforementioned configuration, as means for not connecting the memory cell of the second memory cell array to the bit line, there is provided a configuration in which a gate of the memory cell is not arranged.

According to still another means for solving the problem, there is provided a semiconductor memory device of the present invention, including

a first memory cell array arranging a plurality of memory cells equivalent to memory capacity in a matrix form in a bit line direction and a word line direction,

a first column selection circuit and row selection circuit for respectively selecting a bit line and a word line of the first memory cell array corresponding to an address input,

a plurality of first bit line charge circuits which are connected to the first column selection circuit and respectively charge a plurality of the bit lines selected by the first column selection circuit,

a second memory cell array arranging a plurality of memory cells in a matrix form in a bit line direction and a word line direction,

a second column selection circuit for simultaneously selecting a plurality of bit lines of the second memory cell array, and

a single second bit line charge circuit which is connected to the second column selection circuit and charges the plurality of bit lines of the second memory cell array,

wherein a charge current of the second bit line charge circuit is set larger compared with that of the first bit line charge circuit.

According to still another means for solving the problem, there is provided a semiconductor memory device of the present invention, including

a first memory cell array arranging a plurality of memory cells equivalent to memory capacity in a matrix form in a bit line direction and a word line direction,

a first column selection circuit and row selection circuit for respectively selecting a bit line and a word line of the first memory cell array corresponding to an address input,

a plurality of first bit line charge circuits which are connected to the first column selection circuit and respectively charge a plurality of the bit lines selected by the first column selection circuit,

a second memory cell array arranging a plurality of memory cells in a matrix form in a bit line direction and a word line direction,

a second column selection circuit for simultaneously selecting a plurality of bit lines of the second memory cell array, and

a single second bit line charge circuit which is connected to the second column selection circuit and charges the plurality of bit lines of the second memory cell array,

wherein in the second memory cell array, among the plurality of bit lines simultaneously selected by the second column selection circuit, at least one row of the bit line connects all memory cells, and a threshold voltage of the memory cell connected to at least one row of the bit line is higher than that of the other transistors.

According to still another means for solving the problem, there is provided a semiconductor memory device of the present invention, including

a first memory cell array arranging a plurality of memory cells equivalent to memory capacity in a matrix form in a bit line direction and a word line direction,

a first column selection circuit and row selection circuit for respectively selecting a bit line and a word line of the first memory cell array corresponding to an address input,

a plurality of first bit line charge circuits which are connected to the first column selection circuit and respectively charge a plurality of the bit lines selected by the first column selection circuit,

a second memory cell array arranging a plurality of memory cells in a matrix form in a bit line direction and a word line direction,

a second column selection circuit for simultaneously selecting a plurality of bit lines of the second memory cell array, and

a single second bit line charge circuit which is connected to the second column selection circuit and charges the plurality of bit lines of the second memory cell array,

wherein in the second memory cell array, among the plurality of bit lines simultaneously selected by the second column selection circuit, at least one row of the bit line connects all memory cells, and a negative voltage is supplied to a gate of the memory cell connected to at least one row of the bit line.

According to still another means for solving the problem, there is provided a semiconductor memory device of the present invention, including

a first memory cell array arranging a plurality of memory cells equivalent to memory capacity in a matrix form in a bit line direction and a word line direction,

a first column selection circuit and row selection circuit for respectively selecting a bit line and a word line of the first memory cell array corresponding to an address input,

a plurality of first bit line charge circuits which are connected to the first column selection circuit and respectively charge a plurality of the bit lines selected by the first column selection circuit,

a second memory cell array arranging a plurality of memory cells in a matrix form in a bit line direction and a word line direction,

a second column selection circuit for simultaneously selecting a plurality of bit lines of the second memory cell array,

and a single second bit line charge circuit which is connected to the second column selection circuit and charges the plurality of bit lines of the second memory cell array,

wherein in the second memory cell array, threshold voltages of at least one bit or more memory cells connected to the plurality of bit lines simultaneously selected by the second column selection circuit are higher than those of the other transistors.

According to still another means for solving the problem, there is provided a semiconductor memory device of the present invention, including

a first memory cell array arranging a plurality of memory cells equivalent to memory capacity in a matrix form in a bit line direction and a word line direction,

a first column selection circuit and row selection circuit for respectively selecting a bit line and a word line of the first memory cell array corresponding to an address input,

a plurality of first bit line charge circuits which are connected to the first column selection circuit and respectively charge a plurality of the bit lines selected by the first column selection circuit,

a second memory cell array arranging a plurality of memory cells in a matrix form in a bit line direction and a word line direction,

a second column selection circuit for simultaneously selecting a plurality of bit lines of the second memory cell array, and

a single second bit line charge circuit which is connected to the second column selection circuit and charges the plurality of bit lines of the second memory cell array,

wherein in the second memory cell array, a negative potential is supplied to gates of at least one bit or more memory cells connected to a plurality of bit lines simultaneously selected by the second column selection circuit.

### BRIEF DESCRIPTION OF THE DRAWINGS

FIG. 1A is a plan view of a dummy memory cell array in accordance with a first embodiment of the present invention;

FIG. 1B is a cross-sectional view taken along line A-A of FIG. 1A;

FIG. 1C is a cross-sectional view taken along line B-B of FIG. 1A;

FIG. 1D is a cross-sectional view taken along line C-C of FIG. 1A;

FIG. 1E is a cross-sectional view taken along line D-D of FIG. 1A;

FIG. 2A is a plan view of a dummy memory cell array in accordance with a second embodiment of the present invention;

FIG. 2B is a cross-sectional view taken along line A-A of FIG. 2A;

FIG. 2C is a cross-sectional view taken along line B-B of FIG. 2A;

FIG. 2D is a cross-sectional view taken along line C-C of FIG. 2A;

FIG. 2E is a cross-sectional view taken along line D-D of FIG. 2A;

FIG. 3A is a plan view of a dummy memory cell array in accordance with a third embodiment of the present invention;

FIG. 3B is a cross-sectional view taken along line A-A of FIG. 3A;

FIG. 3C is a cross-sectional view taken along line B-B of FIG. 3A;

FIG. 3D is a cross-sectional view taken along line C-C of FIG. 3A;

FIG. 3E is a cross-sectional view taken along line D-D of FIG. 3A;

FIG. 4 is a replica circuit diagram in accordance with a fourth embodiment of the present invention;

FIG. 5 is a replica circuit diagram in accordance with a fifth embodiment of the present invention;

FIG. 6 is a replica circuit diagram in accordance with a sixth embodiment of the present invention;

FIG. 7 is a replica circuit diagram of a conventional semiconductor memory device;

FIG. 8A is a plan view of a memory cell array of the conventional semiconductor memory device;

FIG. 8B is a cross-sectional view taken along line A-A of FIG. 8A;

FIG. 8C is a cross-sectional view taken along line B-B of FIG. 8A;

FIG. 8D is a cross-sectional view taken along line C-C of FIG. 8A; and

FIG. 9 is a timing chart of a replica circuit of a conventional semiconductor memory device.

### DETAILED DESCRIPTION OF PREFERRED EMBODIMENTS

Hereinafter, referring to the drawings, embodiments according to the present invention will be explained.

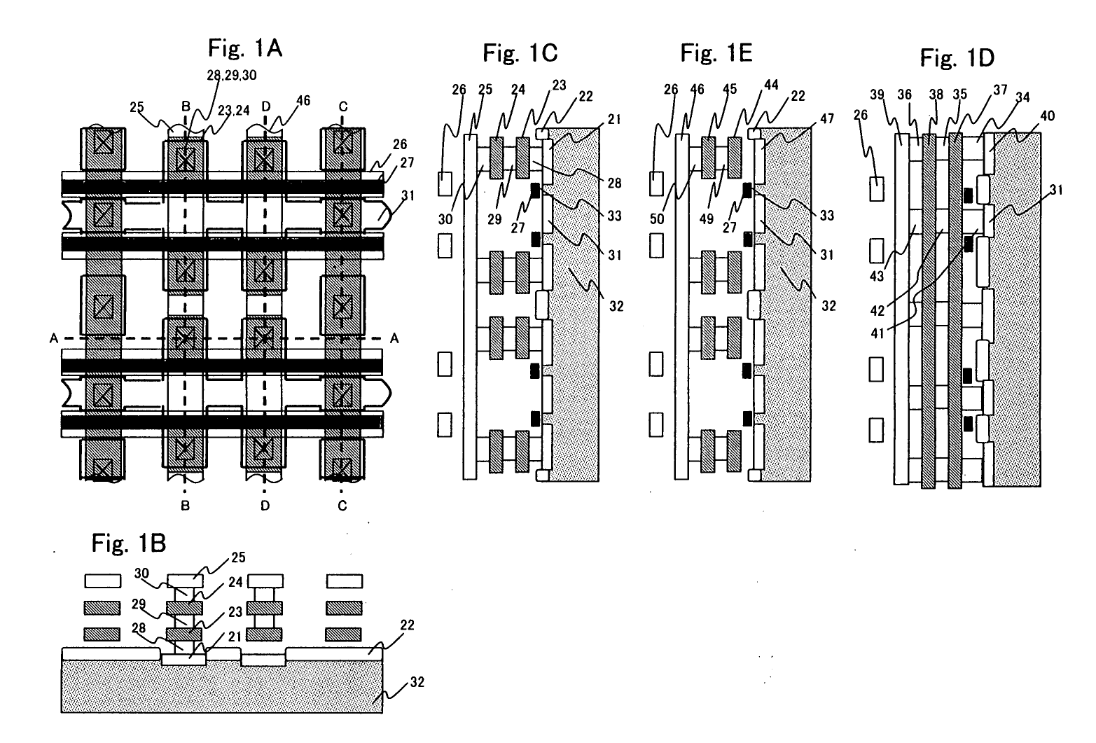

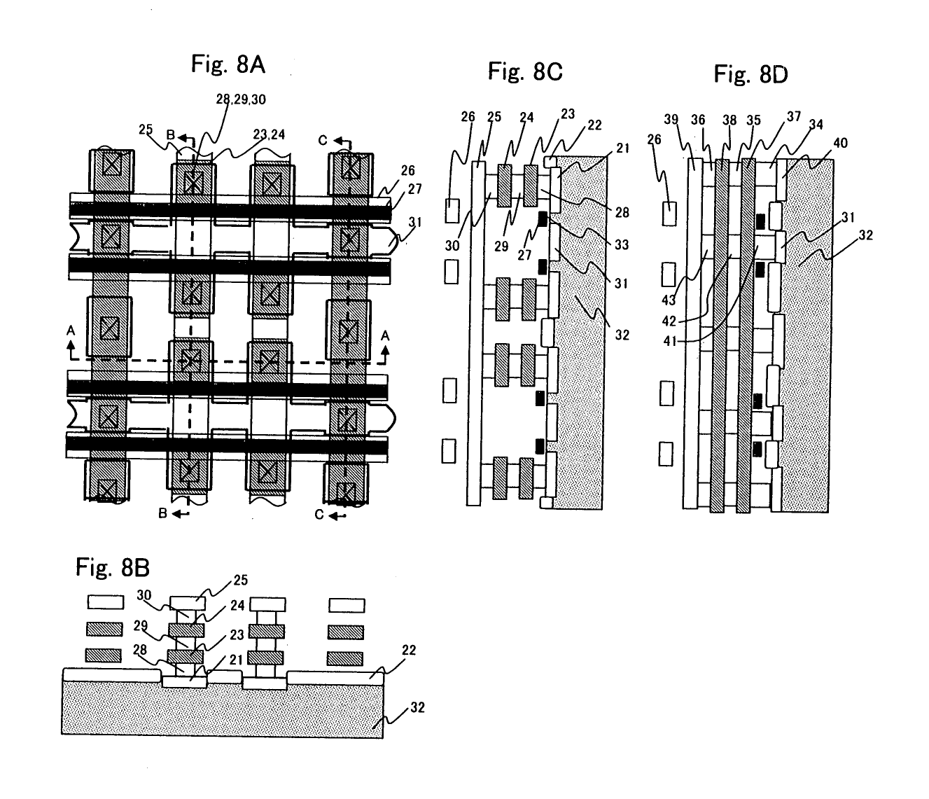

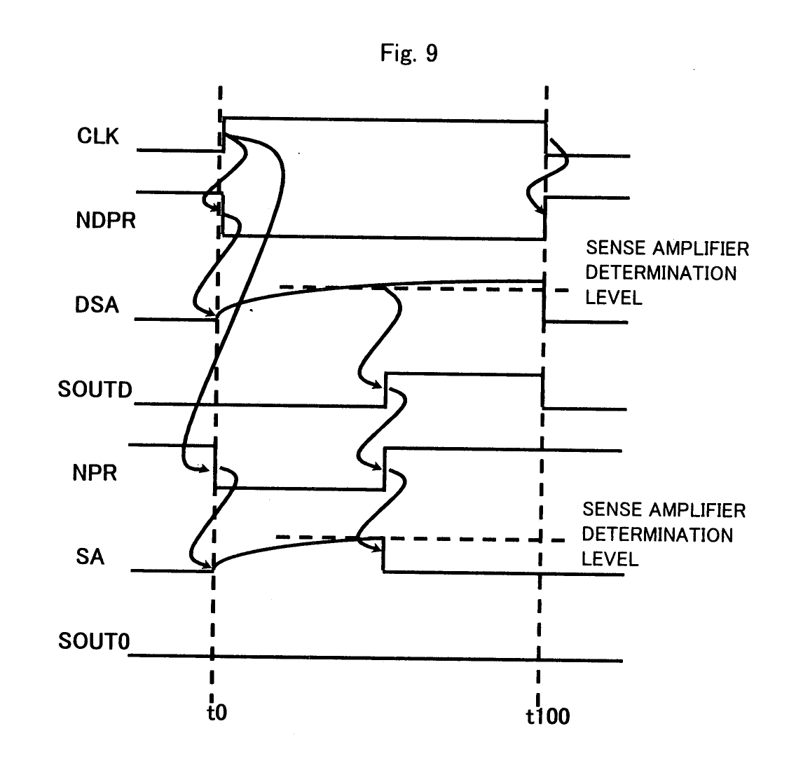

A semiconductor memory device according to a first embodiment of the present invention will be explained referring to the FIG. 1. FIG. 1A is a plan view of a dummy memory cell array in accordance with the first embodiment, and FIG. 1B, FIG. 1C, FIG. 1D, and FIG. 1E are a cross-sectional view taken along line A-A of FIG. 1A, a cross-sectional view taken along line B-B of FIG. 1A, a cross-sectional view taken along line C-C of FIG. 1A, and a cross-sectional view taken along line D-D of FIG. 1A, respectively. In the drawings, since the component having the same reference numeral as that of FIG. 8A, FIG. 8B, FIG. 8C, and FIG. 8D serves a similar function, only different components will be explained.

In FIG. 1, the cross-sectional view taken along line D-D of FIG. 1A, namely FIG. 1E, is different from that of FIG. 8. A portion for interconnecting between a dummy bit line and a drain region of the dummy memory cell is composed of via holes 49 and 50 corresponding to the via holes 29 and 30, metal electrodes 44 and 45 corresponding to the metal electrodes 23 and 24, and a second bit line 46 arranged in parallel with the first dummy bit line 25, while a contact hole corresponding to the contact hole 28 between the drain region 21 of the N-type impurity region and the metal electrode 23 is not provided between a drain region 47 and a metal electrode 44.

As a result of this, among two dummy bit lines charged by the charge circuit, all dummy memory cells are connected to one dummy bit line, while the dummy memory cell is not connected to the other, so that the off leakage current of the dummy memory cell is not excessively increased with respect to the current supply of the charge circuit, thereby making it possible to make the charge potential of the dummy bit line equivalent to that of the normal bit line in the memory array.

Incidentally, in FIG. 1, it is configured in such a way that the contact holes are eliminated by dummy bit line, but even when it is configured in such a way that by the number of a range that the off leakage current generated in two dummy bit lines by the dummy memory cell becomes equivalent to the current of the normal bit line in the memory array by the current supply of the charge circuit, the dummy memory cells are arbitrarily connected to the dummy bit line, and the contact holes of the remaining dummy memory cells are eliminated therefrom, the same effect will be obtained.

Alternatively, even when it is configured in such a way that the via hole 49 or the via hole 50 is eliminated, the same effect may be obtained.

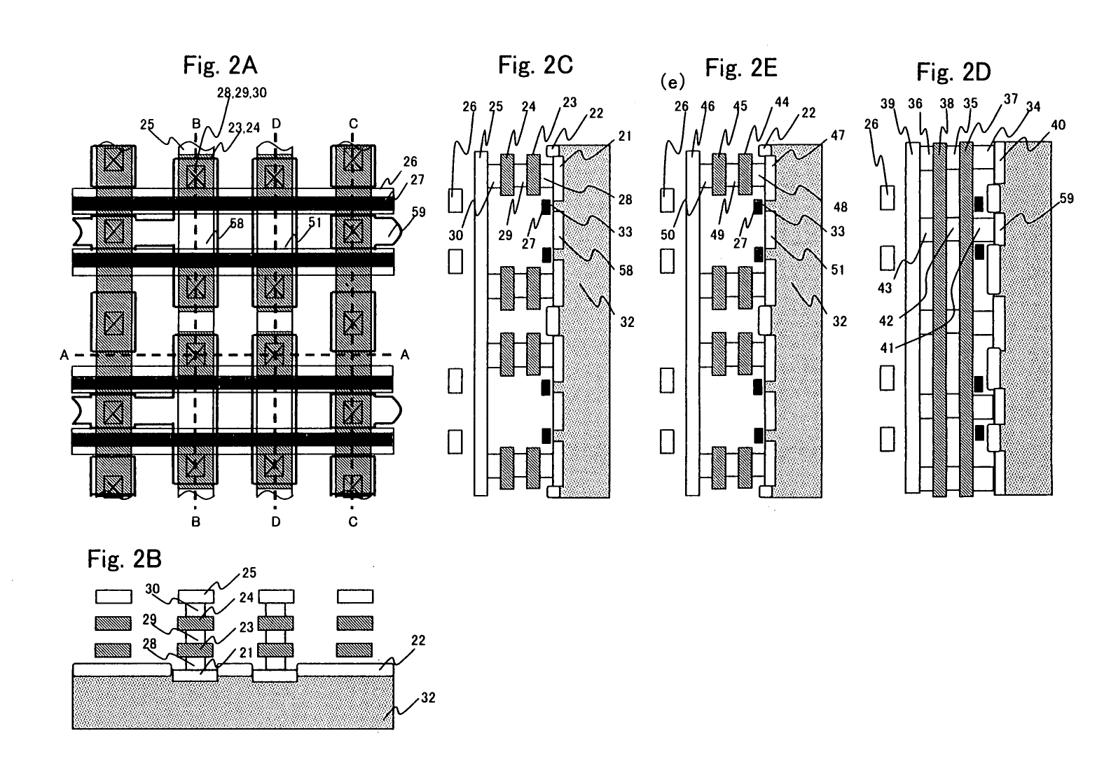

A semiconductor memory device according to a second embodiment of the present invention will be explained referring to FIG. 2. FIG. 2A is a plan view of a dummy memory cell array in accordance with the second embodiment, and FIG. 2B, FIG. 2C, FIG. 2D, and FIG. 2E are a cross-sectional view taken along line A-A of FIG. 2A, a cross-sectional view taken along line B-B of FIG. 2A, a cross-sectional view taken along line C-C of FIG. 2A, and a cross-sectional view taken along line D-D of FIG. 2A, respectively. In the drawings, since the component having the same reference numeral as that of FIG. 8A, FIG. 8B, FIG. 8C, FIG. 8D and FIG. 1 serves a similar function, only different components will be explained.

In the second embodiment, unlike the first embodiment, a contact hole 48 is provided on the drain region 47, a source region 51 of the dummy bit line 46 is kept in a floating state without being connected with others, and a source region 58 of the dummy bit line 25 is isolated from a source region 59 of the source potential supply interconnection 39 used as the ground potential.

As a result of this, among two dummy bit lines charged by the charge circuit, all dummy memory cells are connected to one dummy bit line, and the other does not generate the off leakage current since the source region of the dummy memory cell is kept in a floating state, so that the off leakage current of the dummy memory cell is not excessively increased with respect to the current supply of the charge circuit, thereby making it possible to make the charge potential of the dummy bit line equivalent to that of the normal bit line in the memory array.

Incidentally, in FIG. 2, it is configured in such a way that the source region is kept in a floating state by dummy bit line, but even when it is configured in such a way that by the number of a range that the off leakage current generated in two dummy bit lines by the dummy memory cell becomes equivalent to the current of the normal bit line in the memory array by the current supply of the charge circuit, the dummy memory cells are arbitrarily connected to the dummy bit line, and the source regions of the remaining dummy memory cells are kept in a floating state, the same effect will be obtained.

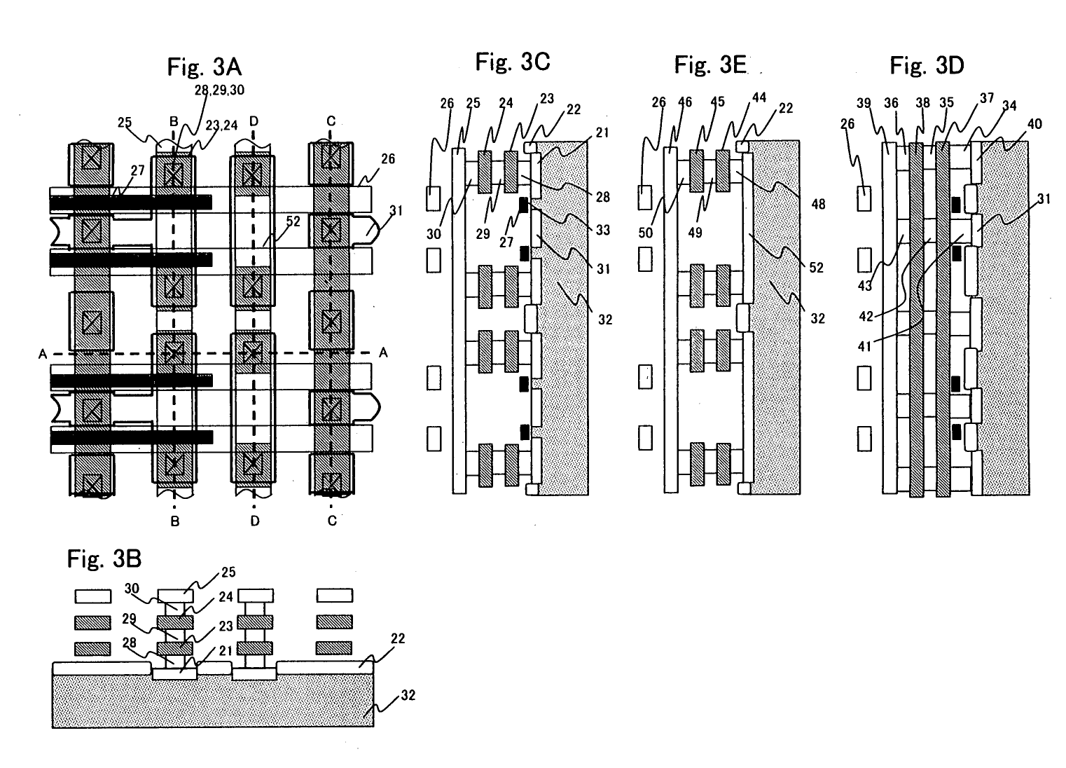

A semiconductor memory device according to a third embodiment of the present invention will be explained referring to FIG. 3. FIG. 3A is a plan view of a dummy memory cell array in accordance with the third embodiment, and FIG. 3B, FIG. 3C, FIG. 3D, and FIG. 3E are a cross-sectional view taken along line A-A of FIG. 3A, a cross-sectional view taken along line B-B of FIG. 3A, a cross-sectional view taken along line C-C of FIG. 3A, and a cross-sectional view taken along line D-D of FIG. 3A, respectively. In the drawings, since the component having the same reference numeral as that of FIG. 8A, FIG. 8B, FIG. 8C, FIG. 8D and FIG. 2 serves a similar function, only different component will be explained.

In this embodiment, without forming the gate electrode 27 (refer to FIG. 8) of the dummy memory cell, the source and drain regions 21 and 31 (refer to FIG. 8) are connected in common in a bit line direction to form a diffusion region 52.

As a result of this, among two dummy bit lines charged by the charge circuit, all dummy memory cells are connected to one dummy bit line, and the off leakage current is not generated from the other dummy bit line since the dummy memory cell is not formed as the transistor in the other, so that the off leakage current of the dummy memory cell is not excessively increased with respect to the current supply of the charge circuit, thereby making it possible to make the charge potential of the dummy bit line equivalent to that of the normal bit line in the memory array.

Incidentally, in FIG. 3, it is configured in such a way that the dummy memory cell is not formed by dummy bit line, but even when it is configured in such a way that by the number of a range that the off leakage current generated in two dummy bit lines by the dummy memory cell becomes equivalent to the current of the normal bit line in the memory array by the current supply of the charge circuit, the dummy memory cells are arbitrarily connected to the dummy bit line, and the transistors are not formed in the remaining dummy memory cells, the same effect will be obtained.

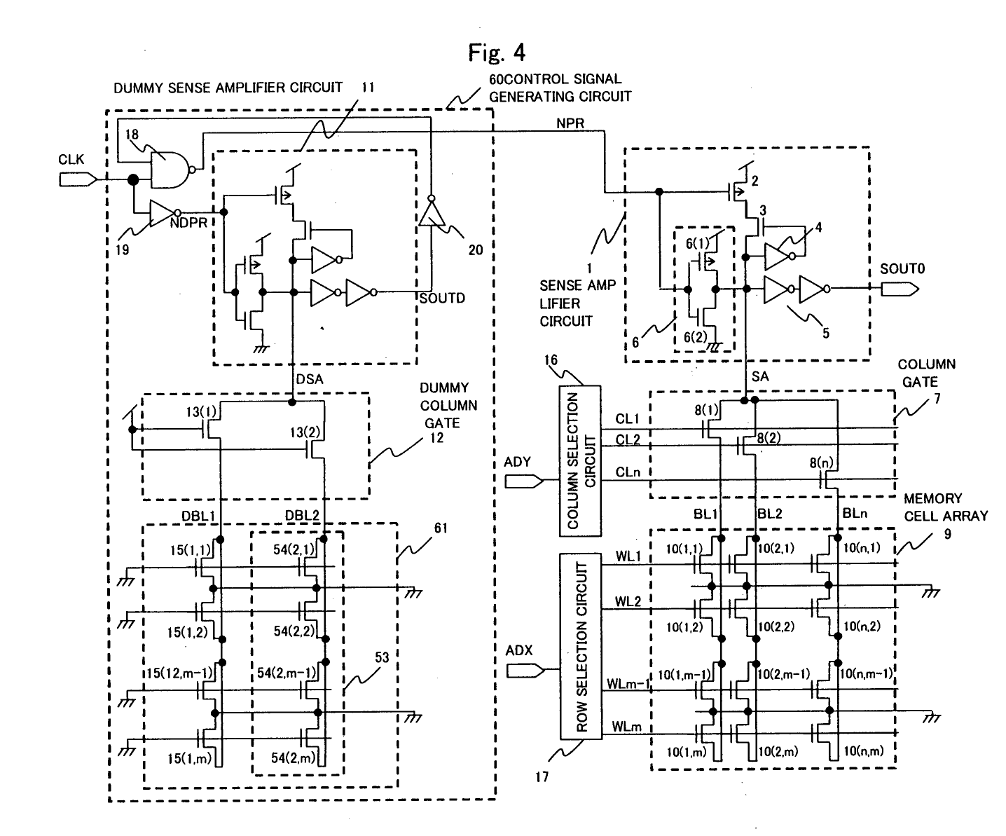

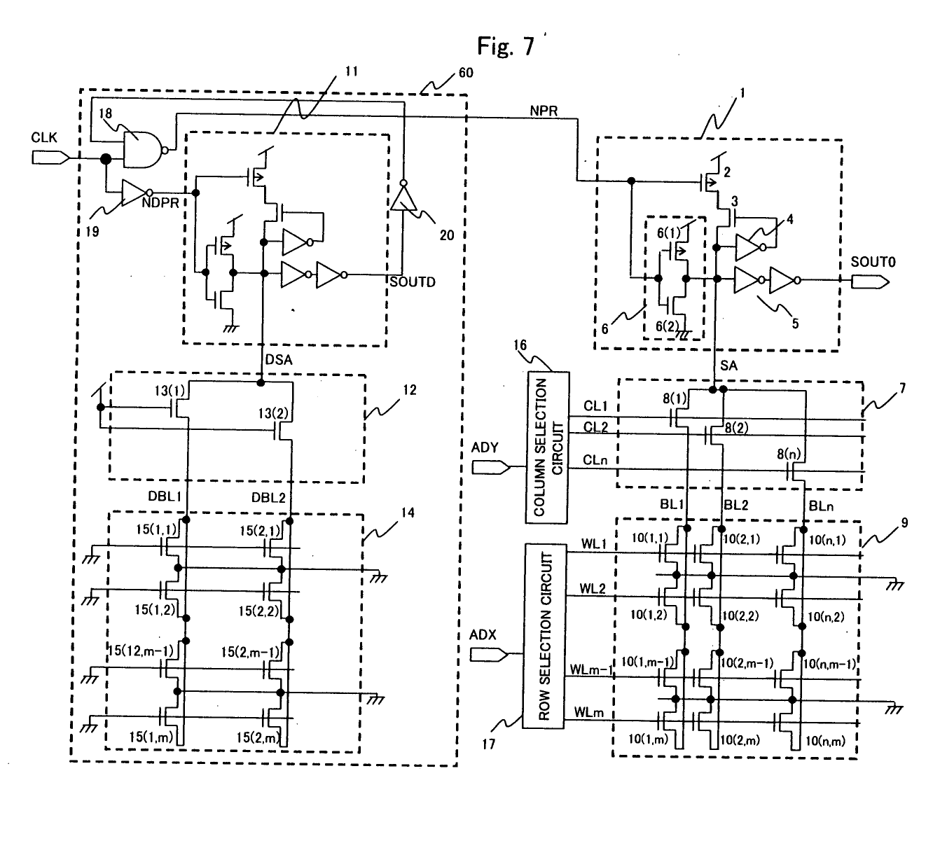

A semiconductor memory device according to a fourth embodiment of the present invention will be explained referring to FIG. 4. FIG. 4 is a readout circuit diagram of a MASK ROM in accordance with the fourth embodiment. In the drawings, since the component having the same reference numeral as that of FIG. 7 serves a similar function, only different components will be explained.

A dummy memory cell array 61 is composed of dummy memory cells 15 (1, 1) through 15 (1, m) and dummy memory cells 54 (2, 1) through 54 (2, m), and threshold voltages of the dummy memory cells 54 (2, 1) through 54 (2, m) are set higher than those of the other memory cells and dummy memory cells.

As a result of this, among two dummy bit lines charged by the charge circuit, one dummy bit line does not generate a large amount of off leakage currents since the threshold voltage of the dummy memory cell is set higher, so that the off leakage current of the dummy memory cell is not excessively increased with respect to the current supply of the charge circuit, thereby making it possible to make the charge potential of the dummy bit line equivalent to that of the normal bit line in the memory array.

Incidentally, in FIG. 4, it is configured in such a way that the threshold voltage of the dummy memory cell is set higher by dummy bit line, but even when it is configured in such a way that by the number of a range that the off leakage current generated in two dummy bit lines by the dummy memory cell becomes equivalent to the current of the normal bit line in the memory array by the current supply of the charge circuit, the threshold voltage of the dummy memory cell is arbitrarily set higher, the same effect will be obtained.

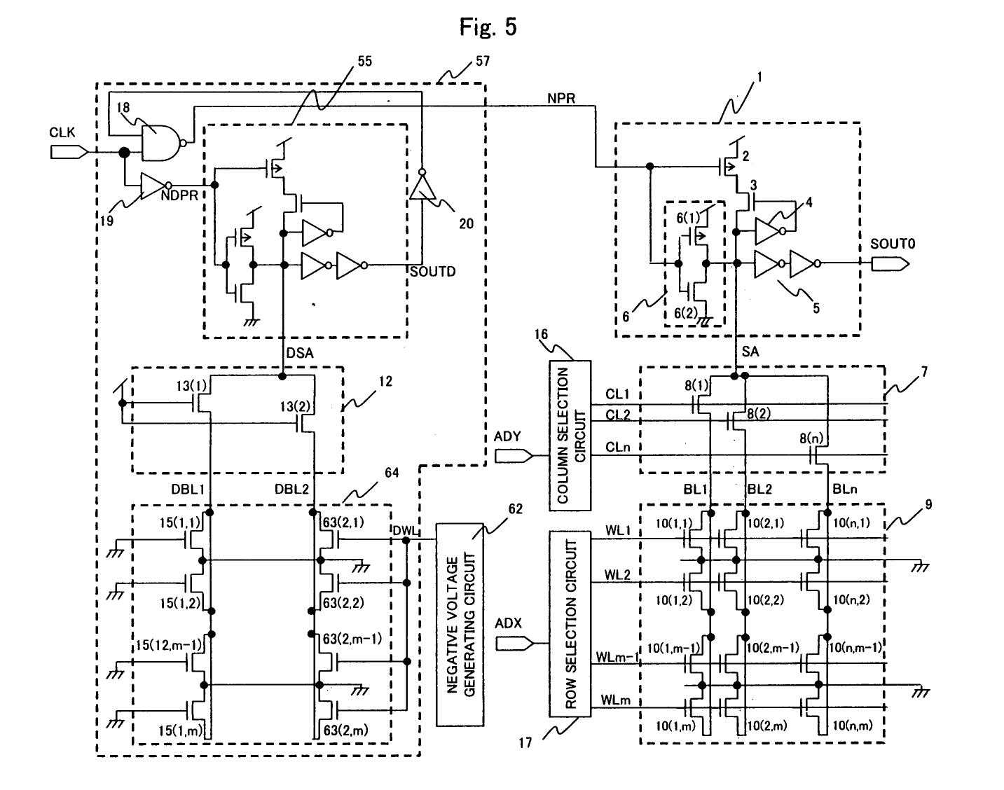

A semiconductor memory device according to a fifth embodiment of the present invention will be explained referring to FIG. 5. FIG. 5 is a readout circuit diagram of a MASK ROM in accordance with the fifth embodiment. In the drawings, since the component having the same reference numeral as that of FIG. 7 serves a similar function, only different components will be explained.

A dummy memory cell array 64 is composed of dummy memory cells 15 (1, 1) through 15 (1, m) and dummy memory cells 63 (2, 1) through 63 (2, m). A negative voltage generating circuit 62 connects a negative voltage signal DWL which serves as a negative potential to a source potential of the dummy memory cells 63 (2, 1) through 63 (2, m) with the gates of the dummy memory cells 63 (2, 1) through 63 (2, m) composed of a part of the transistors of the dummy memory cell array 64 in a control signal generating circuit 57.

As a result of this, among two dummy bit lines charged by the charge circuit, one dummy bit line does not generate a large amount of off leakage currents since a potential which is a negative potential to the source of the dummy memory cell is supplied to the gate of the dummy memory cell, so that the off leakage current of the dummy memory cell is not excessively increased with respect to the current supply of the charge circuit, thereby making it possible to make the charge potential of the dummy bit line equivalent to that of the normal bit line in the memory array.

Incidentally, in FIG. 5, it is configured in such a way that the potential which is the negative potential to the source of the dummy memory cell is inputted to the gate of the dummy memory cell by dummy bit line, but even when it is configured in such a way that by the number of a range that the off leakage current generated in two dummy bit lines by the dummy memory cell becomes equivalent to the current of the normal bit line in the memory array by the current supply of the charge circuit, the gate of the dummy memory cell is arbitrarily set to a negative potential, the same effect will be obtained.

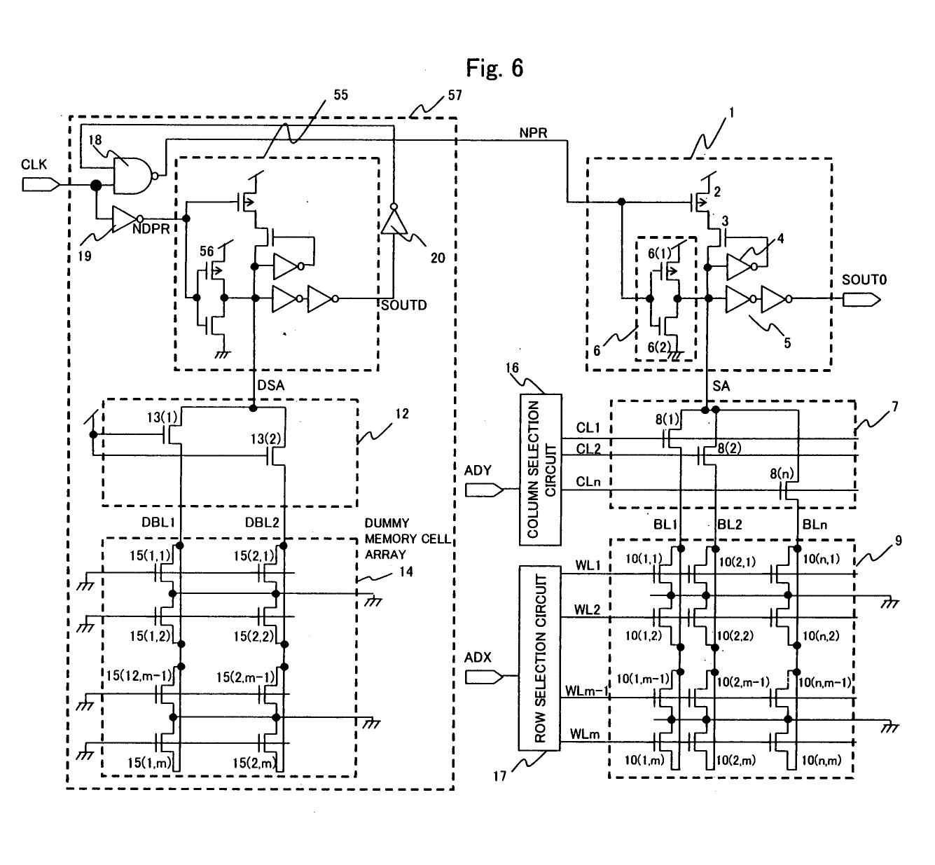

A semiconductor memory device according to a sixth embodiment of the present invention will be explained referring to FIG. 6. FIG. 6 is a readout circuit diagram of a MASK ROM in accordance with the sixth embodiment. In the drawings, since the component having the same reference numeral as that of FIG. 7 serves a similar function, only different components will be explained.

In a dummy sense amplifier 55, a current capacity of a P-type transistor 56 is set higher than that of the P-type transistor 6 (1) of the sense amplifier 1 by two times.

As a result of this, without causing a potential effect from the off leakage current generated by the current supplied from the charge circuit between the two dummy bit lines, the current of the dummy bit line can be equivalent to that of the normal bit line in the memory array.

Incidentally, in the present invention, as means for not connecting the memory cells to the bit line, it is possible to provide a configuration in which by using the same mask as that for writing data to the MASK ROM, a drain of the memory cell and the bit line are not connected.

The semiconductor memory device according to the present invention has advantages allowing the off leakage current of the dummy bit line to be suppressed, the proper timing margin in the readout operation to be secured, or the like, and is useful for the MASK ROM or the like.

What is claimed is:

1. A semiconductor memory device comprising:
a first memory cell array arranging a plurality of memory cells equivalent to memory capacity in a matrix form in a bit line direction and a word line direction;
a first column selection circuit and row selection circuit for respectively selecting a bit line and a word line of said first memory cell array corresponding to an address input;
a plurality of first bit line charge circuits which are connected to said first column selection circuit and respectively charge a plurality of said bit lines selected by said first column selection circuit;
a second memory cell array arranging a plurality of memory cells in a matrix form in a bit line direction and a word line direction;
a second column selection circuit for simultaneously selecting a plurality of bit lines of said second memory cell array; and
a single second bit line charge circuit which is connected to said second column selection circuit and charges said plurality of bit lines of said second memory cell array,
wherein in said second memory cell array, among the plurality of bit lines simultaneously selected by said second column selection circuit, all memory cells are connected to at least one row of the bit line, and at least one row of the bit line does not connect one bit or more memory cells.

2. The semiconductor memory device according to claim 1, wherein in the second memory cell array, as means for not connecting the memory cell to the bit line, a drain of said memory cell and said bit line are not connected.

3. The semiconductor memory device according to claim 1, wherein in the second memory cell array, as means for not connecting the memory cell to the bit line, there is formed such a configuration that by using the same mask as that for writing data to a MASK ROM, a drain of said memory cell and said bit line are not connected.

4. The semiconductor memory device according to claim 1, wherein in the second memory cell array, as means for not connecting the memory cell to the bit line, a source of said memory cell is not connected to a ground potential.

5. The semiconductor memory device according to claim 1, wherein in the second memory cell array, as means for not connecting the memory cell to the bit line, a gate of said memory cell is not arranged.

6. A semiconductor memory device comprising:
a first memory cell array arranging a plurality of memory cells equivalent to memory capacity in a matrix form in a bit line direction and a word line direction;
a first column selection circuit and row selection circuit for respectively selecting a bit line and a word line of said first memory cell array corresponding to an address input;
a plurality of first bit line charge circuits which are connected to said first column selection circuit and respectively charge a plurality of said bit lines selected by said first column selection circuit;
a second memory cell array arranging a plurality of memory cells in a matrix form in a bit line direction and a word line direction;
a second column selection circuit for simultaneously selecting a plurality of bit lines of said second memory cell array;
and a single second bit line charge circuit which is connected to said second column selection circuit and charges said plurality of bit lines of said second memory cell array,
wherein in said second memory cell array, the plurality of bit lines simultaneously selected by said second column selection circuit do not connect at least one bit or more memory cells.

7. The semiconductor memory device according to claim 6, wherein in the second memory cell array, as means for not connecting the memory cell to the bit line, a drain of said memory cell and said bit line are not connected.

8. The semiconductor memory device according to claim 6, wherein in the second memory cell array, as means for not connecting the memory cell to the bit line, there is formed such a configuration that by using the same mask as that for writing data to a MASK ROM, a drain of the memory cell and the bit line are not connected.

9. The semiconductor memory device according to claim 6, wherein in the second memory cell array, as means for not connecting the memory cell to the bit line, a source of said memory cell is not connected to a ground potential.

10. The semiconductor memory device according to claim 6, wherein in the second memory cell array, as means for not connecting the memory cell to the bit line, a gate of said memory cell is not arranged.

11. A semiconductor memory device comprising:
a first memory cell array arranging a plurality of memory cells equivalent to memory capacity in a matrix form in a bit line direction and a word line direction;
a first column selection circuit and row selection circuit for respectively selecting a bit line and a word line of said first memory cell array corresponding to an address input;
a plurality of first bit line charge circuits which are connected to said first column selection circuit and respectively charge a plurality of said bit lines selected by said first column selection circuit;
a second memory cell array arranging a plurality of memory cells in a matrix form in a bit line direction and a word line direction;
a second column selection circuit for simultaneously selecting a plurality of bit lines of said second memory cell array; and
a single second bit line charge circuit which is connected to said second column selection circuit and charges said plurality of bit lines of said second memory cell array,
wherein a charge current of said second bit line charge circuit is set larger compared with that of the first bit line charge circuit.

12. A semiconductor memory device comprising:
a first memory cell array arranging a plurality of memory cells equivalent to memory capacity in a matrix form in a bit line direction and a word line direction;
a first column selection circuit and row selection circuit for respectively selecting a bit line and a word line of said first memory cell array corresponding to an address input;
a plurality of first bit line charge circuits which are connected to said first column selection circuit and respectively charge a plurality of said bit lines selected by said first column selection circuit;
a second memory cell array arranging a plurality of memory cells in a matrix form in a bit line direction and a word line direction;
a second column selection circuit for simultaneously selecting a plurality of bit lines of said second memory cell array; and
a single second bit line charge circuit which is connected to said second column selection circuit and charges said plurality of bit lines of said second memory cell array,
wherein in said second memory cell array, among the plurality of bit lines simultaneously selected by said second column selection circuit, at least one row of the bit line connects all memory cells, and a threshold voltage of the memory cell connected to at least one row of the bit line is higher than threshold voltages of the other transistors.

13. A semiconductor memory device comprising:
a first memory cell array arranging a plurality of memory cells equivalent to memory capacity in a matrix form in a bit line direction and a word line direction;
a first column selection circuit and row selection circuit for respectively selecting a bit line and a word line of said first memory cell array corresponding to an address input;
a plurality of first bit line charge circuits which are connected to said first column selection circuit and respectively charge a plurality of said bit lines selected by said first column selection circuit;
a second memory cell array arranging a plurality of memory cells in a matrix form in a bit line direction and a word line direction;
a second column selection circuit for simultaneously selecting a plurality of bit lines of said second memory cell array; and
a single second bit line charge circuit which is connected to said second column selection circuit and charges said plurality of bit lines of said second memory cell array,
wherein in said second memory cell array, among the plurality of bit lines simultaneously selected by said second column selection circuit, at least one row of the bit line connects all memory cells, and a negative voltage is supplied to a gate of the memory cell connected to at least one row of the bit line.

14. A semiconductor memory device comprising:
a first memory cell array arranging a plurality of memory cells equivalent to memory capacity in a matrix form in a bit line direction and a word line direction;
a first column selection circuit and row selection circuit for respectively selecting a bit line and a word line of said first memory cell array corresponding to an address input;
a plurality of first bit line charge circuits which are connected to said first column selection circuit and respectively charge a plurality of said bit lines selected by said first column selection circuit;
a second memory cell array arranging a plurality of memory cells in a matrix form in a bit line direction and a word line direction;
a second column selection circuit for simultaneously selecting a plurality of bit lines of said second memory cell array;
and a single second bit line charge circuit which is connected to said second column selection circuit and charges said plurality of bit lines of said second memory cell array,
wherein in said second memory cell array, threshold voltages of at least one bit or more memory cells connected to a plurality of bit lines simultaneously selected by said second column selection circuit are higher than those of the other transistors.

15. A semiconductor memory device comprising:
a first memory cell array arranging a plurality of memory cells equivalent to memory capacity in a matrix form in a bit line direction and a word line direction;
a first column selection circuit and row selection circuit for respectively selecting a bit line and a word line of said first memory cell array corresponding to an address input;
a plurality of first bit line charge circuits which are connected to said first column selection circuit and respectively charge a plurality of said bit lines selected by said first column selection circuit;
a second memory cell array arranging a plurality of memory cells in a matrix form in a bit line direction and a word line direction;
a second column selection circuit for simultaneously selecting a plurality of bit lines of said second memory cell array; and
a single second bit line charge circuit which is connected to said second column selection circuit and charges said plurality of bit lines of said second memory cell array,
wherein in said second memory cell array, a negative potential is supplied to gates of at least one bit or more memory cells connected to a plurality of bit lines simultaneously selected by said second column selection circuit.
